(19) United States
(12) Patent Application Publication
(10) Pub. No.: US 2026/0188371 A1
(43) Pub. Date: Jul. 2, 2026

(54) READ CIRCUIT OF MEMORY

(71) Applicant: ZHEJIANG HIKSTOR TECHNOLOGY CO., LTD., Hangzhou, Zhejiang (CN)

(72) Inventors: Baoyu XIONG, Hangzhou, Zhejiang (CN); Ao SHEN, Hangzhou, Zhejiang (CN); Ganxiang YU, Hangzhou, Zhejiang (CN); Yiheng DU, Hangzhou, Zhejiang (CN); Jie ZHANG, Hangzhou, Zhejiang (CN)

(21) Appl. No.: 18/860,938

(22) PCT Filed: Nov. 27, 2023
(86) PCT No.: PCT/CN2023/134474

§ 371 Date: Oct. 28, 2024

(30) Foreign Application Priority Data
Nov. 30, 2022 (CN) 202211533718.8

(51) Int. Cl. G11C 11/16

(52) U.S. Cl. CPC G11C 11/1673; G11C 11/1659

(57) ABSTRACT

The present disclosure provides a read circuit of a memory. The read circuit includes: a sense amplifier, a read array connected to the sense amplifier, and a reference circuit. The read circuit includes a plurality of memory cells disposed in a column. The reference circuit includes a reference resistor and a compensation resistor network. The compensation resistor network is configured to match, during a read operation, parasitic resistances of the memory cells at different physical locations of the read array on a transmission path of a data-side current.

The present disclosure claims priority to Chinese patent application No. 2022115337188, filed on Nov. 30, 2022 to the China Patent Office, and entitled “READ CIRCUIT OF MEMORY”, the entire content of which is incorporated herein by reference.

### TECHNICAL FIELD

The present disclosure relates to the technical field of integrated circuit design, in particular to a read circuit of a memory.

### BACKGROUND

Reading information stored in an MRAM is accomplished by detecting the resistance of a memory cell. The resistance of the memory cell has two states, namely a high-resistance state Rap (“AP” state) or a low-resistance state Rp (“P” state). During the read operation, by applying a clamp voltage (Vclamp), the resistance of the memory cell will generate a read current pulse Idata, and a reference current Iref will be generated by applying a reference voltage (Vref) through a reference resistor Rref. By comparing the read current Idata with the reference current Iref, a sense amplifier may recognize whether the memory cell is in the high-resistance state or the low-resistance state, and may read out “1” or “0”.

In the implementation process of the present disclosure, the inventor found at least the following technical problems in the related art:

for memory cells located on the same column, memory cells with different addresses have different lengths of read and write transmission paths due to differences in physical distance. Far-end address fields tend to have more parasitic resistances than near-end address fields. For the same Vclamp, a data-side current of a memory cell located in the far-end address field is written as Idata_far, a data-side current of a memory cell located in the near-end address field is written as Idata_near, and due to the influence of the parasitic resistance of the transmission path, Idata_far<Idata_near is caused. However, the current Iref does not change with the physical location of the memory cell. As shown in FIG. 1, taking reading a P-state memory cell as an example, a read window of the far-end address field may be reduced, which affects the read yield.

### SUMMARY

In order to solve the above problems, the present disclosure provides a read circuit of a memory.

The present disclosure provides a read circuit of a memory. The read circuit includes: a read array including a plurality of memory cells disposed in a column;
a clamp control MOS transistor, a clamp voltage being input to a gate terminal of the clamp control MOS transistor for generating a data-side current on the read array;
a reference circuit including a reference resistor and a compensation resistor network, the compensation resistor network being configured to match, during a read operation, parasitic resistances of the memory cells at different physical locations of the read array on a transmission path of the data-side current;
a reference control MOS transistor, a reference voltage being input to a gate terminal of the reference control MOS transistor for generating a reference-side current on the reference circuit; and
a sense amplifier, one end of the sense amplifier being connected to the read array through the clamp control MOS transistor, the other end of the sense amplifier being connected to the reference circuit through the reference control MOS transistor, and the sense amplifier being configured to output a read result by comparing the data-side current with the reference-side current.

In some embodiments of the present application, each of the memory cells includes a magnetic tunnel junction and a switching transistor connected to the magnetic tunnel junction.

In some embodiments of the present application, the compensation resistor network includes: a plurality of switching transistors and a plurality of compensation resistors, and the quantity of the compensation resistors is one less than the quantity of the switching transistors; and the specific connection manner is: the reference resistor is connected in series with the plurality of compensation resistors in sequence, and each of the reference resistor and the compensation resistors is connected to a ground line through one switching transistor.

In some embodiments of the present application, the switching transistors are N-channel metal oxide semiconductors (NMOSs) or P-channel metal oxide semiconductors (PMOSs).

In some embodiments of the present application, a resistance value of each of the compensation resistors satisfies the following relational equation: R_{com}=N/M*(R_{bl}+Rₛₗ),
and R_{com} denotes the resistance value of the compensation resistor, N denotes the quantity of the memory cells of the read array, M denotes the quantity of the switching transistors of the compensation resistor network, R_{bl} denotes a BL parasitic resistance between each memory cell in the read array, and Rₛₗ denotes an SL parasitic resistance between each memory cell in the read array.

In some embodiments of the present application, the reference resistor has a resistance value between Rp and Rap, Rp denoting a resistance of a magnetic tunnel junction in a parallel state, and Rap denoting a resistance of the magnetic tunnel junction in an antiparallel state.

In some embodiments of the present application, the read circuit further includes:
a first branch switch connected between the clamp control MOS transistor and a bit line of the read array;
a second branch switch connected between a source line of the read array and a ground line; and
a third branch switch connected between the reference resistor and the reference control MOS transistor.

In some embodiments of the present application, the read array includes 2ⁿ memory cells disposed in a column, where n is a positive integer, and on-off states of the switching transistors of the memory cells are controlled by corresponding WL<2ⁿ−1:0> signals.

In some embodiments of the present application, the compensation resistor network includes 2^{m} switching transistors and 2^{m}−1 compensation resistors, where m is a positive integer.

In some embodiments of the present application, the quantity of the memory cells in the read array is greater than or equal to the quantity of the switching transistors in the compensation resistor network.

In some embodiments of the present application, the quantity of the memory cells in the read array is multiplicative to the quantity of the switching transistors in the compensation resistor network.

In some embodiments of the present application, the compensation resistors satisfy the following relational equation:

$${R}_{c o m} = {2}^{n - m} ( {R}_{bl} + {R}_{sl} ) \qquad ( m \leq n )$$

where R_{bl} denotes a BL parasitic resistance between the memory cells in the read array, Rₛₗ denotes an SL parasitic resistance between the memory cells in the read array, the read array includes 2ⁿ memory cells disposed in a column, and the compensation resistor network includes 2^{m} switching transistors.

According to some embodiments of the present application, n=10, and m=2.

In some embodiments of the present application, the quantity of the switching transistors in the compensation resistor network is directly proportional to the accuracy of compensation for the parasitic resistances of the memory cells on the transmission path of the data-side current.

In some embodiments of the present application, a first end of the first branch switch K1 is connected to a first memory cell of the read array, a second end of the first branch switch K1 is connected to a source of the clamp control MOS transistor, and a drain of the clamp control MOS transistor is electrically connected to a first input end of the sense amplifier.

In some embodiments of the present application, a first end of the second branch switch K2 is connected to a first memory cell of the read array, and a second end of the second branch switch K2 is grounded.

In some embodiments of the present application, a first end of the third branch switch K3 is connected to the reference resistor, a second end of the third branch switch K3 is connected to a source of the reference control MOS transistor, and a drain of the reference control MOS transistor is electrically connected to a second input end of the sense amplifier.

### BRIEF DESCRIPTION OF THE DRAWINGS

FIG. 1 is a schematic diagram of the reduction of a read window caused by the difference of parasitic resistances at near and far ends in the related art.

FIG. 2 is a schematic structural diagram of a read circuit of a memory according to some embodiments of the present disclosure.

FIG. 3 is a schematic structural diagram of a read circuit of a memory according to some embodiments of the present disclosure.

FIG. 4 is a schematic diagram of the effect of applying the present disclosure to avoid inconsistency of read windows at different physical locations.

The above figures include the following reference numerals:
101. Read array; and 102, compensation resistor network.

### DETAILED DESCRIPTION OF THE EMBODIMENTS

In order to make the objective, technical solutions and advantages of embodiments of the present disclosure clearer, the technical solutions in the embodiments of the present application will be clearly and completely described below in conjunction with the accompanying drawings in the embodiments of the present application. Apparently, the described embodiments are merely a part of the embodiments of the present disclosure, rather than all the embodiments. Based on the embodiments of the present disclosure, all other embodiments obtained by those of ordinary skill in the art without creative work shall fall within the scope of protection of the present disclosure.

It is to be noted that the terms “first”, “second” and the like in the description, claims and drawings of the present disclosure are used for distinguishing between similar objects and not necessarily for describing a particular sequential or chronological order. It is to be understood that the data so used are interchangeable under appropriate circumstances so that the embodiments of the present disclosure described herein may be implemented in sequences other than those illustrated or described herein. Moreover, the terms “include” and “have”, and any variation thereof, are intended to cover a non-exclusive inclusion, for example, a process, method, system, product, or device that includes a list of steps or elements is not necessarily limited to those steps or elements expressly listed, but may include other steps or elements not expressly listed or inherent to such process, method, product, or device.

In the present disclosure, the terms “upper”, “lower”, “left”, “right”, “front”, “back”, “top”, “bottom”, “inner”, “outer”, “center”, “vertical”, “horizontal”, “transverse”, “longitudinal”, etc. indicate an orientation or positional relationship based on that shown in the accompanying drawings. These terms are primarily intended to better describe the present disclosure and embodiments thereof, and are not intended to qualify that the indicated apparatus, element, or component must have a particular orientation, or be constructed and operated in a particular orientation.

Moreover, some of the above terms may be used to indicate other meanings in addition to the orientation or positional relationship, for example, the term “on” may also be used in some cases to indicate a certain dependency or connection relationship. The specific meaning of these terms in the present disclosure may be understood by those of ordinary skill in the art depending on the particular circumstances.

In addition, the terms “installed”, “disposed”, “provided with”, “connecting”, “connected”, and “sleeved” should be understood in a broad sense. For example, it may be a fixed connection, a removable connection, or an integral construction; it may be a mechanical connection, or an electrical connection; it may be a direct connection, or an indirect connection by means of an intermediate medium, or an internal connection between two apparatuses, elements or components. The specific meaning of the above terms in the present disclosure may be understood by those ordinary skill in the art depending on the particular circumstances.

Some implementations of the present disclosure are described in detail below in conjunction with the accompanying drawings. The following embodiments and features in the embodiments may be combined with each other without conflict.

Some embodiments of the present disclosure provide a read circuit of a memory. The read circuit includes a read array, a clamp control MOS transistor, a reference circuit, a reference control MOS transistor, and a sense amplifier.

The read array includes a plurality of memory cells disposed in a column.

A clamp voltage is input to a gate terminal of the clamp control MOS transistor for generating a data-side current on the read array.

The reference circuit includes a reference resistor and a compensation resistor network. The compensation resistor network is configured to match, during a read operation, parasitic resistances of the memory cells at different physical locations of the read array on a transmission path of the data-side current.

A reference voltage is input to a gate terminal of the reference control MOS transistor for generating a reference-side current on the reference circuit.

One end of the sense amplifier is connected to the read array through the clamp control MOS transistor, and the other end of the sense amplifier is connected to the reference circuit through the reference control MOS transistor. The sense amplifier is configured to output a read result by comparing the data-side current with the reference-side current.

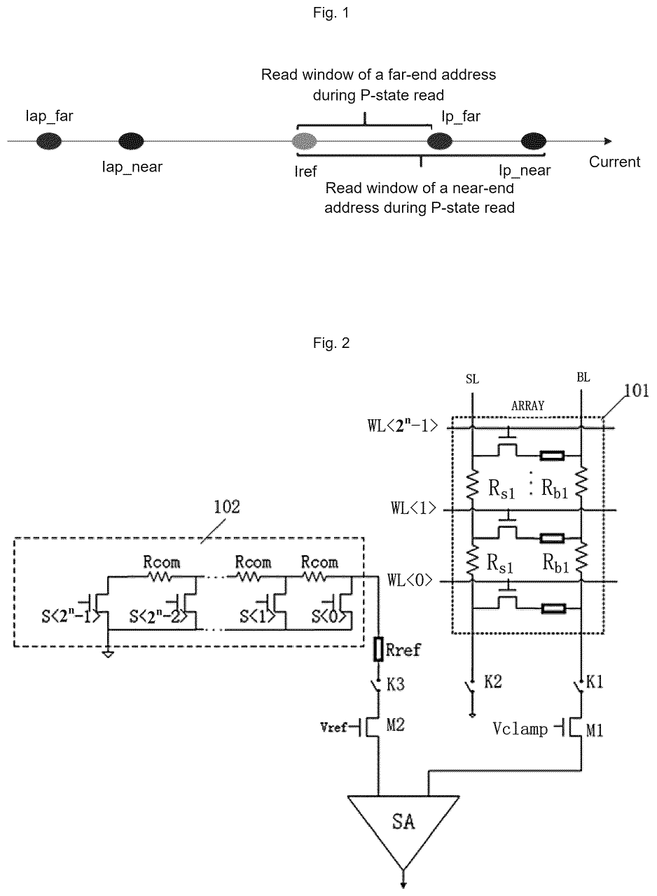

As an implementation, FIG. 2 shows a schematic structural diagram of the read circuit of the memory. As shown in FIG. 2, the read circuit of the memory includes: a read array 101, a clamp control MOS transistor M1, a reference circuit, a reference control MOS transistor M2, and a sense amplifier SA.

The read array 101 may be any column of a memory array, and includes 2ⁿ (n is a positive integer) memory cells disposed in a column. Each of the memory cells includes a magnetic tunnel junction and a switching transistor connected to the magnetic tunnel junction. The on-off states of the switching transistors of the memory cells are controlled by the corresponding WL<2ⁿ−1:0> signals.

A clamp voltage Vclamp is input to a gate terminal of the clamp control MOS transistor M1 for generating a data-side current on the read array.

The reference circuit includes a reference resistor Rref and a compensation resistor network 102. The compensation resistor network 102 is configured to match, during a read operation, parasitic resistances of the memory cells at different physical locations of the read array 101 on a transmission path of the data-side current.

A reference voltage Vref is input to a gate terminal of the reference control MOS transistor M2 for generating a reference-side current on the reference circuit.

One end of the sense amplifier SA is connected to the read array 101 through the clamp control MOS transistor M1, and the other end of the sense amplifier SA is connected to the reference circuit through the reference control MOS transistor M2. The sense amplifier is configured to output a read result by comparing the data-side current with the reference-side current.

Specifically, the quantity of the memory cells in the read array is greater than or equal to the quantity of the switching transistors in the compensation resistor network.

Specifically, the quantity of the memory cells in the read array is multiplicative to the quantity of the switching transistors in the compensation resistor network.

Specifically, in these embodiments, the compensation resistor network 102 includes 2^{m} switching transistors S<2^{m}−1:0> and 2^{m-1} compensation resistors (m is a positive integer, and m≤n). The specific connection manner is that the reference resistor Rref is connected in series with the 2^{m-1} compensation resistors in sequence, and each of the reference resistor and the compensation resistors is connected to a ground line through one switching transistor. The switching transistors may be NMOSs or PMOSs. NMOSs are used in these embodiments. Each of the compensation resistors is R_{com} and satisfies the following relational equation:

$${R}_{c o m} = {2}^{n - m} ( {R}_{bl} + {R}_{sl} ) \qquad ( m \leq n )$$

and R_{bl} denotes a BL parasitic resistance between each memory cell in the read array, and Rₛₗ denotes an SL parasitic resistance between each memory cell in the read array.

The reference resistor Rref has a resistance value between Rp and Rap, Rp denoting a resistance of the magnetic tunnel junction in a parallel state, and Rap denoting a resistance of the magnetic tunnel junction in an antiparallel state.

In addition, the read circuit of the memory according to these embodiments further includes:
a first branch switch K1 connected between the clamp control MOS transistor M1 and a bit line of the read array 101;
a second branch switch K2 connected between a source line of the read array 101 and the ground line; and
a third branch switch K3 connected between the reference resistor and the reference control MOS transistor M2. By means of the branch switches, different read arrays may be selected, and data from whichever column is connected is read.

A first end of the first branch switch K1 is connected to a first memory cell of the read array, a second end of the first branch switch K1 is connected to a source of the clamp control MOS transistor, and a drain of the clamp control MOS transistor is electrically connected to a first input end of the sense amplifier.

A first end of the second branch switch K2 is connected to a first memory cell of the read array, and a second end of the second branch switch K2 is grounded.

A first end of the third branch switch K3 is connected to the reference resistor, a second end of the third branch switch K3 is connected to a source of the reference control MOS transistor, and a drain of the reference control MOS transistor is electrically connected to a second input end of the sense amplifier.

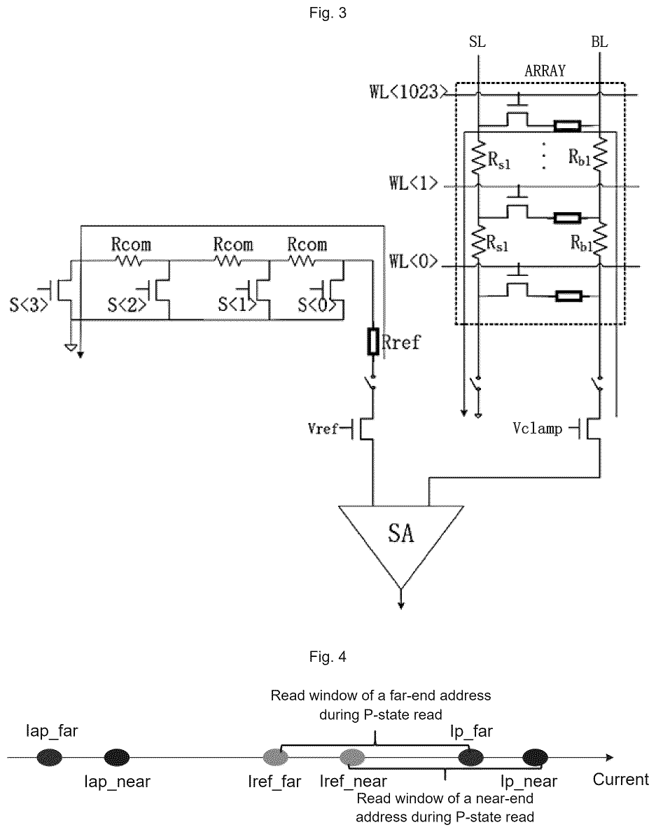

As an implementation, referring to FIG. 3, the read circuit includes a sense amplifier SA, a reference circuit and a read array. The read array includes 1024 (i.e., 210) memory cells, and the on-off states of switching transistors of the memory cells are controlled by the corresponding WL<1023:0> signals. The BL parasitic resistance between the memory cells is R_{bl}, and the SL parasitic resistance between the memory cells is Rₛₗ. A compensation resistor network includes four (i.e., 2²) switching transistors and three compensation resistors, and each compensation resistor satisfies R_{com}=2⁸*(R_{bl}+Rₛₗ).

The specific compensation method of this circuit is as follows: during the read operation, Vref, Vclamp, and branch switches K1, K2, and K3 are turned on to read the nearest 256 memory cells (256 memory cells controlled by WL<0>-WL<255>), and a switching transistor S<0> is switched on without compensation; the subsequent 256 memory cells (256 memory cells controlled by WL<256>-WL<511>) are read, a switching transistor S<1> is switched on, and parasitic resistance compensation is performed with one compensation resistor, which is equivalent to compensating for the parasitic resistance of the previous 256 memory cells on the transmission path; another subsequent 256 memory cells (256 memory cells controlled by WL<512>-WL<767>) are read, a switching transistor S<2> is switched on, and parasitic resistance compensation is performed with two compensation resistors, which is equivalent to compensating for the parasitic resistance of the previous 512 memory cells on the transmission path; and the farthest 256 memory cells (256 memory cells controlled by WL<768>-WL<1023>) are read, a switching transistor S<3> is switched on, and parasitic resistance compensation is performed with three compensation resistors, which is equivalent to compensating for the parasitic resistance of the previous 768 memory cells on the transmission path. The more switching transistors and the more adjustment gears, the more accurate the compensation will be, and the quantity of the switching transistors determines the accuracy of the read circuit provided by the present disclosure for compensating for parasitic resistances. That is, the quantity of the switching transistors in the compensation resistor network is directly proportional to the accuracy of compensation for the parasitic resistances of the memory cells on the transmission path of the data-side current.

As shown in FIG. 3, by controlling the word line WL<1023>, a memory cell to be read is selected, and S<3> is opened while the word line WL<1023> is opened, so that the reference-side current flows through three compensation resistors in the compensation resistor network, thereby matching the parasitic resistances when the data-side current flows through the path in the read array, and avoiding the problem that read windows are inconsistent in the case of reading memory cells at different physical locations. FIG. 4 illustrates that after applying the read circuit of the embodiments of the present disclosure, the read windows may be consistent in the case of reading memory cells at different physical locations.

Although the quantity of the memory cells and the quantity of the switching transistors in the above embodiments both satisfy an exponential power of 2, it is not necessary for the actual circuit to meet this requirement. Generally, a certain multiplicative relationship between the quantity of the memory cells and the quantity of the switching transistors is sufficient, and the purpose of satisfying the multiplicative relationship is that adjustment gears are evenly spaced.

Generally, the resistance value of each compensation resistor satisfies the following relational equation: R_{com}=N/M*(R_{bl}+Rₛₗ).
and R_{com} denotes the resistance value of the compensation resistor, N denotes the quantity of the memory cells of the read array, M denotes the quantity of the switching transistors of the compensation resistor network, R_{bl} denotes a BL parasitic resistance between the memory cells in the read array, and Rₛₗ denotes an SL parasitic resistance between the memory cells in the read array.

To illustrate, for example, the memory array includes 100 memory cells, the compensation resistor network includes ten switching transistors and nine compensation resistors, and the resistance value of each compensation resistor satisfies the following relational equation: R_{com}=10*(R_{bl}+Rₛₗ), so the compensation method is as follows: read the nearest ten memory cells without compensation, read the eleventh to twentieth memory cells, compensated by one compensation resistor, read the twenty-first to thirtieth memory cells, compensated by two compensation resistors, and so on.

The foregoing are only specific implementations of the present disclosure, but the scope of protection of the present disclosure is not limited thereto, and any variation or substitution readily conceivable by any person skilled in the art within the technical scope disclosed in the present disclosure shall be covered by the scope of protection of the present disclosure. Accordingly, the scope of protection of the present disclosure shall be as set forth in the claims.

What is claimed is:

1. A read circuit of a memory, comprising:
a read array comprising a plurality of memory cells disposed in a column;
a clamp control MOS transistor, a clamp voltage being input to a gate terminal of the clamp control MOS transistor for generating a data-side current on the read array;
a reference circuit comprising a reference resistor and a compensation resistor network, the compensation resistor network being configured to match, during a read operation, parasitic resistances of the memory cells at different physical locations of the read array on a transmission path of the data-side current;
a reference control MOS transistor, a reference voltage being input to a gate terminal of the reference control MOS transistor for generating a reference-side current on the reference circuit; and
a sense amplifier, one end of the sense amplifier being connected to the read array through the clamp control MOS transistor, the other end of the sense amplifier being connected to the reference circuit through the reference control MOS transistor, and the sense amplifier being configured to output a read result by comparing the data-side current with the reference-side current.

2. The read circuit of a memory according to claim 1, wherein each of the memory cells comprises a magnetic tunnel junction and a switching transistor connected to the magnetic tunnel junction.

3. The read circuit of a memory according to claim 1, wherein the compensation resistor network comprises:
a plurality of switching transistors and a plurality of compensation resistors, wherein the quantity of the compensation resistors is one less than the quantity of the switching transistors; and the specific connection manner is: the reference resistor is connected in series with the plurality of compensation resistors in sequence, and each of the reference resistor and the compensation resistors is connected to a ground line through one switching transistor.

4. The read circuit of a memory according to claim 3, wherein the switching transistors are N-channel metal oxide semiconductors (NMOSs) or P-channel metal oxide semiconductors (PMOSs).

5. The read circuit of a memory according to claim 3, wherein a resistance value of each of the compensation resistors satisfies the relational equation: Rcom=N/M*(Rbl+Rsl),
wherein Rcom denotes the resistance value of the compensation resistor, N denotes the quantity of the memory cells of the read array, M denotes the quantity of the switching transistors of the compensation resistor network, Rbl denotes a BL parasitic resistance between each memory cell in the read array, and Rsl denotes an SL parasitic resistance between each memory cell in the read array.

6. The read circuit of a memory according to claim 1, wherein the reference resistor has a resistance value between Rp and Rap, Rp denoting a resistance of a magnetic tunnel junction in a parallel state, and Rap denoting a resistance of the magnetic tunnel junction in an antiparallel state.

7. The read circuit of a memory according to claim 1, further comprising:
a first branch switch connected between the clamp control MOS transistor and a bit line of the read array;
a second branch switch connected between a source line of the read array and a ground line; and
a third branch switch connected between the reference resistor and the reference control MOS transistor.

8. The read circuit of a memory according to claim 2, wherein the read array comprises 2n memory cells disposed in a column, wherein n is a positive integer, and on-off states of the switching transistors of the memory cells are controlled by corresponding WL<2n−1:0> signals.

9. The read circuit of a memory according to claim 4, wherein the compensation resistor network comprises 2m switching transistors and 2m−1 compensation resistors, wherein m is a positive integer.

10. The read circuit of a memory according to claim 4, wherein the quantity of the memory cells in the read array is greater than or equal to the quantity of the switching transistors in the compensation resistor network.

11. The read circuit of a memory according to claim 10, wherein the quantity of the memory cells in the read array is multiplicative to the quantity of the switching transistors in the compensation resistor network.

12. The read circuit of a memory according to claim 4, wherein the compensation resistors satisfy the following relational equation:
$$Rcom = 2 n - m ( Rb l + Rsl ) \qquad ( m \leq n )$$
wherein Rbl denotes a BL parasitic resistance between the memory cells in the read array, Rsl denotes an SL parasitic resistance between the memory cells in the read array, the read array comprises 2n memory cells disposed in a column, and the compensation resistor network comprises 2m switching transistors.

13. The read circuit of a memory according to claim 12, wherein n=10 and m=2.

14. The read circuit of a memory according to claim 4, wherein the quantity of the switching transistors in the compensation resistor network is directly proportional to the accuracy of compensation for the parasitic resistances of the memory cells on the transmission path of the data-side current.

15. The read circuit of a memory according to claim 7, wherein a first end of the first branch switch K1 is connected to a first memory cell of the read array, a second end of the first branch switch K1 is connected to a source of the clamp control MOS transistor, and a drain of the clamp control MOS transistor is electrically connected to a first input end of the sense amplifier.

16. The read circuit of a memory according to claim 7, wherein a first end of the second branch switch K2 is connected to a first memory cell of the read array, and a second end of the second branch switch K2 is grounded.

17. The read circuit of a memory according to claim 7, wherein a first end of the third branch switch K3 is connected to the reference resistor, a second end of the third branch switch K3 is connected to a source of the reference control MOS transistor, and a drain of the reference control MOS transistor is electrically connected to a second input end of the sense amplifier.
